(19) United States
(12) Patent Application Publication
(10) Pub. No.: US 2003/0002351 A1
(43) Pub. Date: Jan. 2, 2003

(54) Integrated memory circuit and method for reading a data item from a memory cell

(76) Inventors: Peter Beer, Tutzing (DE); Herbert Benzinger, Munchen (DE); Arndt Gruber, Munchen (DE); Reidar Stief, Munchen (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/178,646

(22) Filed: Jun. 24, 2002

(30) Foreign Application Priority Data
Jun. 23, 2001 (DE) 101 30 363.7

(51) Int. Cl. G11C 5/00

(52) U.S. Cl. 365/189.07

(57) ABSTRACT

An integrated memory circuit includes a memory cell addressed through a first word line and read through a first bit line. The first word line is connected to a word line control circuit for activating, based upon an address, a first word line associated with the memory cell to be read. A data item stored in the addressable memory cell is read through the first bit line using a read apparatus, in particular, a sense amplifier. A second word line is provided to connect a capacitance element to a second bit line, the second bit line being adjacent to the first bit line. The word line control circuit is adapted to connect the capacitance element to the second bit line using the second word line substantially simultaneously with activation of the first word line. A method for reading the data item is also provided.

### BACKGROUND OF THE INVENTION

1. Field of the Invention

The invention relates to an integrated memory circuit having a memory cell that can be addressed through a word line and can be read through a bit line. The invention also relates to a method for reading a data item from such a memory cell.

Conventional memory circuits normally have memory cells that are disposed in a matrix-like array and can be addressed through word lines and bit lines. The bit lines are connected in pairs to a respective sense amplifier that amplifies small charge differences on the bit line pairs. The sense amplifier is turned on when, by activating a respective word line, the charge contents of the memory cells addressed as a result have been applied to the corresponding bit lines. The sense amplifier then amplifies the small charge difference on a bit line pair's adjacent bit lines by separating the charges on the adjacent bit lines in different directions, i.e., the charge on the bit line with the lower charge is reduced and the charge on the bit line with the higher charge is increased. As such, the data item stored as charge in the memory cell is amplified and can, thus, be read explicitly.

The sense amplifier's amplification of the charge difference causes a rapid potential change on the bit lines that results in signal overcoupling on respectively adjacent bit lines. The signal overcoupling has a negative influence on the evaluation or assessment of the memory content.

In addition, the reading of the memory content is also adversely affected by the capacitive coupling between the bit lines. To reduce the occurrences of capacitive coupling from one bit line to an adjacent one during the evaluation of a memory cell, twisted lines are used to reduce the coupling between two bit lines in this way. Preferably, the bit lines in a bit line pair are twisted, so that the occurrences of coupling between bit lines in different bit line pairs compensate for one another in the best case.

However, the use of twisted lines is successful only if the capacitances of the respective bit lines are of equal size. When the content of a memory cell in the memory chip is assessed, the memory cell is connected to a bit line. During the assessment, the bit line is compared with the adjacent bit line in the bit line pair, to which adjacent bit line there is normally no memory cell connected at this moment. If the differences in the line capacitances on account of construction differences are disregarded, the capacitances of the adjacent bit lines then differ precisely by the capacitance of a memory cell. By way of example, the capacitance of a memory cell is approximately ⅕ of the capacitance of the bit line, so that, in the read state, there is a capacitance difference between the adjacent bit lines of approximately 20%.

The different capacitance of the adjacent bit lines connected to the respective sense amplifier causes the voltage swing on one of the bit lines to be different than the voltage swing on the adjacent bit lines during amplification. Such a situation can cause the effective gain by the sense amplifier to be lower than originally intended. To compensate for the effect, the sense amplifiers can be configured to have a higher gain, for example, but this means that the sense amplifiers will take up a greater amount of chip area.

### SUMMARY OF THE INVENTION

It is accordingly an object of the invention to provide an integrated memory circuit and method for reading a data item from a memory cell that overcomes the hereinafore-mentioned disadvantages of the heretofore-known devices and methods of this general type and in which an addressed memory cell can be read more reliably, particularly, in which adverse signal overcoupling effects can be reduced. It is also an object of the invention to provide an improved method for reading a memory cell.

With the foregoing and other objects in view, there is provided, in accordance with the invention, a n integrated memory circuit, including word lines including a first word line and a second word line, a word line control circuit having an input for receiving an address and adapted to activate at least the first word line based upon the address received at the input, the first and second word lines connected to the word line control circuit, bit lines including a first bit line and a second bit line, a memory cell connected to at least the first word line and at least the first bit line, the memory cell addressed through the first word line and having a content read through the first bit line, at least one capacitance element connected to the second word line, the second word line being adapted to apply the at least one capacitance element to the second bit line adjacent an activated the first bit line upon activation of the second word line, and the word line control circuit adapted to apply the at least one capacitance element to the second bit line through the second word line during activation of the first word line.

Alternatively and/or additionally, the word line control circuit can be programmed to activate at least the first word line based upon the address received at the input, the first and second word lines connected to the word line control circuit, and the word line control circuit can be programmed to apply the at least one capacitance element to the second bit line through the second word line during activation of the first word line.

The invention provides an integrated memory circuit having a memory cell that can be addressed through a first word line and can be read through a first bit line. The first word line is connected to a word line control circuit for the purpose of activating the first word line, which is associated with the memory cell to be read, based upon an address., A data item stored in the addressed memory cell can be read through the first bit line using a read apparatus. A second word line is provided to connect a capacitance element to a second bit line. In this case, the second bit line is adjacent to the first bit line. The word line control circuit is configured so as to connect the capacitance element to the second bit line using the second word line substantially simultaneously with activation of the first word line.

With the objects of the invention in view, there is also provided a method for reading a data item from a memory cell through a first bit line connected to the memory cell, including the steps of providing a second bit line adjacent the first bit line, increasing capacitance of the second bit line by connecting a capacitance to the second bit line, reading the memory cell by activating a word line and causing a charge stored in the memory cell to flow onto the first bit line, amplifying a charge difference between the first bit line and the adjacent second bit line and reading the data item stored in the memory cell through the first bit line.

Based upon the method, provision is made for the capacitance of a second bit line, which is substantially adjacent to the first bit line, to be increased first by connecting the second bit line to a capacitance element, for example. Substantially simultaneously or subsequently, the first word line is activated, so that a charge stored in the memory cell flows onto the first bit line. Next, the charge difference between the first bit line and the second bit line is amplified, so that the amplified charge potential can be read through the first bit line as the data item stored in the memory cell.

The invention has the advantage that, in a memory circuit having a plurality of bit lines that are adjacent to one another, faults resulting from occurrences of capacitive coupling on account of capacitance differences between the bit lines can be reduced or eliminated. This is achieved by virtue of the read operation and the subsequent amplification of the data item that is read involving matching the capacitance of the adjacent bit line or of the adjacent bit lines to the respective capacitance of the bit line with the memory cell that is to be read.

To this end, a capacitance element is connected to the bit line adjacent to the respectively activated bit line by activating an additional word line substantially simultaneously with the first word line. In this case, the capacitance element preferably has the same capacitance as the memory cell that is to be read, so that the total capacitance of the two adjacent bit lines is substantially the same after the capacitance component has been connected and after the respective memory cell has been activated. If the construction of the bit lines is approximately the same (and, hence, the capacitances are approximately the same), the capacitance element, therefore, preferably has substantially the same type of construction as the memory cell that is to be read.

In accordance with another embodiment, provision can be made for a plurality of second bit lines to be provided that respectively have capacitance elements disposed on them. In this way, the respective capacitance element can be connected to all the second bit lines when activating the second word line. This is also a way of simultaneously reading from a plurality of memory cells because capacitance equalization is always effected for the first bit lines.

Preferably, two second word lines can be provided that control one or more capacitance elements, the capacitance elements being disposed such that they can be connected to different bit lines. In such a case, provision is preferably made for one of the second word lines to actuate capacitance elements on every second bit line, with the other one of the second word lines actuating capacitance elements on the respective other bit lines. As such, whenever one of the bit lines is activated, the capacitances of the bit lines adjacent thereto can be increased by activating a respective one of the second word lines.

In accordance with another feature of the invention, there is provided at least one dummy memory cell, the at least one capacitance element being contained in the at least one dummy memory cell.

In accordance with a further feature of the invention, the memory cell has a given capacitance when addressed and the at least one capacitance element substantially has the given capacitance.

In accordance with an added feature of the invention, the first bit line is a plurality of first bit lines, each of the first bit lines has an associated adjacent bit line to form respective bit line pairs, and one of a plurality of sense amplifiers is connected to each of the bit line pairs.

In accordance with an additional feature of the invention, the bit lines include a plurality of first and second bit lines having capacitance elements and the second word line is connected to apply the capacitance elements to every second one of the first and second bit lines when the second word line is activated.

In accordance with yet another feature of the invention, the word lines include a plurality of second word lines having a respective plurality of capacitance elements and the capacitance elements are adapted to be applied to different ones of the bit lines.

With reference to the inventive method, provision is also made for the first and second bit lines to have an equal predetermined voltage potential applied to them when the adjacent bit line has been connected to a capacitance element and before the word line is activated. This is advantageous so that the same charges are on the two bit lines before the charge in the memory cell flows onto the first bit line.

So that the charge on the second bit line is not substantially influenced even when the capacitance element is connected to the second bit line, provision is made for the capacitance element also to be charged to the predetermined voltage potential, which is also on the first and second bit lines. This makes it possible for even small charge differences on the bit lines to be clearly identifiable and to be able to be amplified by the sense amplifier based upon the prescribed gain. The same capacitance on the bit lines then guarantees that the gain is not adversely affected by occurrences of signal coupling.

In accordance with a concomitant mode of the invention, the capacitance of the adjacent bit line is selected to make capacitances of the bit line and of the adjacent bit line substantially the same.

Other features that are considered as characteristic for the invention are set forth in the appended claims.

Although the invention is illustrated and described herein as embodied in an integrated memory circuit and method for reading a data item from a memory cell, it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIG. 1 is a block circuit diagram of a memory circuit in accordance with an embodiment of the invention in a precharged state; and

FIG. 2 is a block circuit diagram of the memory circuit of FIG. 1 in a read state.

### DESCRIPTION OF THE PREFERRED EMBODIMENTS

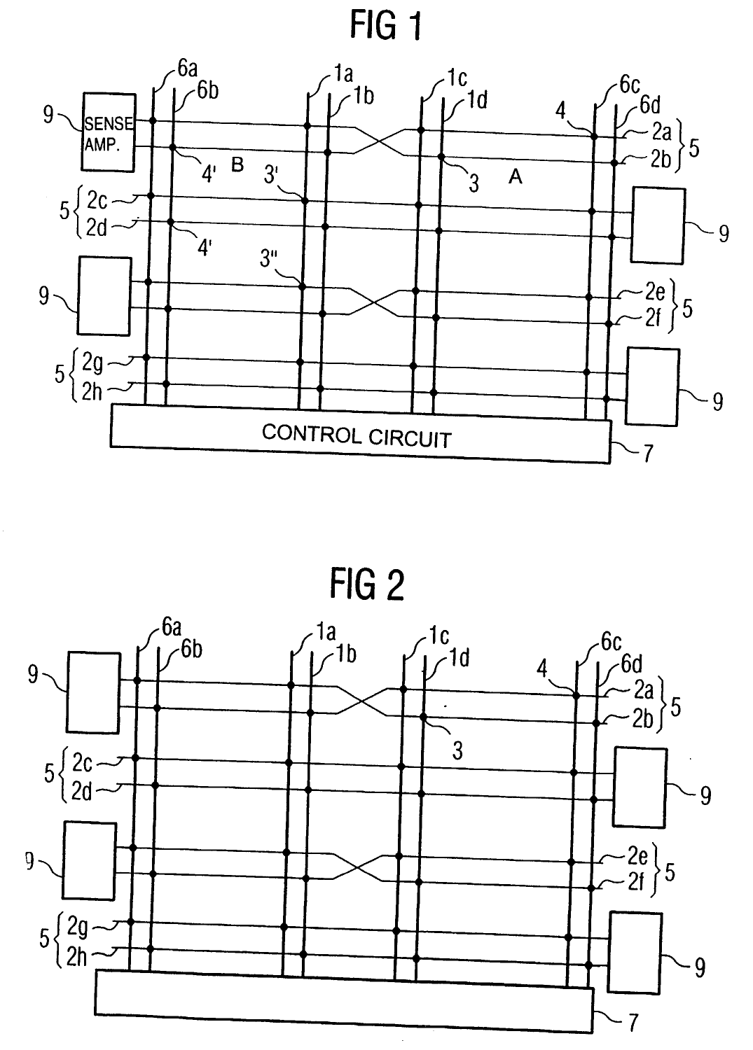

Referring now to the figures of the drawings in detail and first, particularly to FIG. 1 thereof, there is shown a memory circuit having word lines 1a-1d and bit lines 2a-2h. This is preferably a DRAM memory circuit. Disposed at crossover points between word lines 1a-1d and bit lines 2a-2h are memory cells 3, with each of the word lines 1a-1d having a memory cell 3 only at crossover points with every second bit line 2a, 2c, 2e, 2g; 2b, 2d, 2f, 2h. The bit lines 2a-2h are disposed in pairs in bit line pairs 5 and are connected in pairs to a respective sense amplifier 9. A word line control circuit 7 actuates the word lines 1a-1d. The word line control circuit 7 undertakes conversion of an address for the memory cell 3 to a word line address that indicates which of the word lines 1a-1d needs to be activated in order to apply the charge content of an addressed memory cell 3 to the respective bit line 2a-2h.

The bit lines 2a-2h in the bit line pairs 5, e.g., the bit lines 2a, 2b, can swap over their paths, i.e., can be twisted, so that signal changes on bit line 2c, respectively adjacent to a bit line 2a, 2b, in an adjacent bit line pair 5 influence the bit lines to the same extent. If the voltage potential on the bit line 2c changes, the voltage change on the bit line 2c influences the charge potential on the bit line 2b in a section A of the memory circuit and influences the charge potential of the bit line 2a in a section B.

The bit lines 2a, 2b are normally twisted such that the sections A and B are approximately the same length, which means that the signal coupling between the bit lines 2a-2b and the bit line 2c is approximately the same. If the bit lines 2a, 2b are twisted a plurality of times, then the length of the sections situated between the twists can preferably be chosen such that the cross-talking signal on the bit line 2c in a bit line pair 5 adjacent thereto affects each of the relevant bit lines 2a, 2b to the same extent.

When reading a memory cell 3′, the respective word line 1a is first activated, so that the addressed memory cells 3, 3′ are connected to the respective bit lines 2b, 2c, 2f, 2g. The charge in the memory cells 3 on the word line then flows onto the respective addressed bit lines 2b, 2c, 2f, 2g. This results in a charge difference between the bit lines 2b, 2c, 2f, 2g with the addressed memory cells 3 and their respective adjacent bit lines 2a, 2d, 2e, 2h in the same bit line pair 5. At the same time, the capacitance of the bit lines 2b, 2c, 2f, 2g with the memory cells 3, 3′ activated by the word line 1a is increased by the capacitance of a memory cell 3.

The ratio of the coupling capacitance of the bit line 2c with the connected memory cell 3′ to the natural capacitance of the bit lines 2a, 2d adjacent thereto determines the amount by which the adjacent bit line 2a, 2d is additionally coupled. The capacitance ratio, thus, determines the amount by which the charge difference to be read is reduced between the bit lines 2a-2h in the bit line pair 5. If the capacitance of the adjacent bit line 2a, 2d is increased before or during reading of the addressed bit line 2c, then the uncoupled capacitance share is increased and the adverse attenuation as a result of signal overcoupling is reduced. This means that the charge difference stored in the memory cell 3′ is increased and a greater charge is available for reading.

According to the invention, the capacitance of the adjacent bit lines 2a, 2d is increased by connecting a dummy memory cell 4 to the bit line 2a, 2d adjacent to the bit line 2c simultaneously with activation of the respective word line 1a to increase the capacitance of the adjacent bit line 2a, 2d. To connect the-respective dummy memory cell 4 to the adjacent bit lines 2a, 2d, additional word-lines 6a-6d are provided that are likewise actuated by the word line control circuit 7.

If, in one example, a memory cell 3′ on the word line 1a and on the bit line 2c is then addressed, the charge in the memory cell 3′ flows onto the addressed bit line 2c and increases the charge potential available there. At the same time, the effective capacitance of the bit line 2c is increased by the amount of the capacitance of the memory cell 3′.

Substantially simultaneously with activation of the word line 1a, the dummy memory cells 4′ are connected to the adjacent bit lines 2a, 2d by activating the additional word line 6b. The effect achieved by this activation is that the effective capacitances of the bit line 2c and of the adjacent bit lines 2a, 2d are the same. This results in the bit lines 2a, 2d adjacent to the bit line 2c respectively having the same capacitance as the bit line 2b during amplification of the charge difference by the sense amplifier 9. Such a configuration reduces the coupling of the adjacent bit lines 2a, 2d during assessment because the capacitance of the adjacent bit lines 2a, 2d is brought more into line with the capacitance of the activated bit line 2c.

The dummy memory cells 4 are provided such that, for each of the additional word lines 6a-6d, a dummy memory cell 4 is provided on every second bit line 2a-2h. The additional word lines 6a-6d are connected in the opposite direction to the respective active word line 1a-1d by the word line control circuit 7, so that the additional word line 6a-6d is activated respectively, which additional word lines have dummy memory cells 4 connected to them that are not on the respective active bit line 2a-2h but rather on the adjacent bit lines 2a-2h.

If the bit lines 2a-2h in the memory circuit are twisted to some extent, the configuration produces a plurality of sections A, B for the bit lines 2a-2h. To ensure, as described above, that the bit lines 2a-2h adjacent to the respective activated bit lines 2a-2h have an additional capacitance applied to them by connecting a dummy memory cell 4, additional word lines 6a-6d need to be provided for each of the sections A, B. This is necessary because twisting the bit lines 2a-2h alters the regular order of the bit lines 2a-2h, which means that dummy memory cells 4 previously spaced apart from one another by a respective bit line 2a-2h can be situated on an additional word line 6a-6d next to one another. The additional word lines 6a-6d in a section A, B are actuated such that an addressed word line 1a-1d is used to activate an additional word line in the same section A, B. For this reason, two additional word lines 6a, 6b; 6c, 6d are used for each section A, B of the memory circuit.

Depending on the size of the charge difference that can be found between the bit line 2a-2h and the adjacent bit line 2a-2h when the charge in the respective addressed memory cell 3 has been connected, reading by the sense amplifier 9 is effected more quickly or more slowly. The sense amplifier 9 spreads the bit line signals more quickly the greater the size of the existing charge difference.

If, in one example, a memory cell 3′ with a weak signal and a memory cell 3″ with a strong signal are situated next to one another, as illustrated, the respective charges are applied to the respective bit line 2c or 2f when the word line 1a is activated. Because the corresponding sense amplifier 9 spreads the charges on the bit lines 2e and 2f more quickly than the charges on the bit lines 2c and 2d, the bit line 2d adjacent to the activated bit line 2c is actually influenced by a signal change on the bit line 2f even before the sense amplifier 9 amplifies the charge difference between the bit lines 2c and 2d. The bit line 2f for the strong memory cell 3″ is then actually coupled into the bit line 2d by the read operation before the read operation starts for the memory cell 3 with the weak signal. This can result in the charge difference on the bit lines 2c, 2d being reversed, as a result of which, the memory content is read incorrectly.

Even if the bit line 2f and its adjacent bit line 2e for the memory cell 3″ with the strong signal are spread asymmetrically, the coupling, due to the capacitance differences, onto the adjacent bit line 2d for the memory cell 3′ with the weak signal is greater than the coupling onto the bit line 2c, and the signal is attenuated. This is the case particularly when the contents, i.e., the logical contents, of the memory cells 3′, 3″ are the same.

To read a data item from a memory cell 3, the capacitance of the bit line 2a-2h that is adjacent to the activated bit line 2a-2h is first increased before the first word line 1a-1d is activated. The capacitance is increased by activating the additional word line 6a-6d associated with the respectively adjacent bit lines 2a-2h. When the charge difference between the bit line 2a-2h and the adjacent bit line 2a-2h has been amplified, the data item, which is in the form of a charge difference, is read.

FIG. 1 shows the integrated memory circuit in a pre-charged state. To put the charge difference on the bit lines 2a-2h into a defined initial state, it is appropriate to pre-charge both the bit lines 2a-2h in a bit line pair 5 and the dummy memory cells 4 before activation of the word line 1a-1d using a particular voltage potential. This is preferably done by activating the additional word lines 6a-6d, which connect the dummy memory cells 4 to the bit lines 2a-2h, so that all the dummy memory cells 4 are connected to the bit lines 2a-2h. If charge equalization is performed on the respectively adjacent bit lines 2a-2h in the pre-charged state, then the same voltage potential is applied both to the bit lines 2a-2h and in the dummy memory cells 4. The result of this is that connecting the dummy memory cell 4 onto the bit line 2a-2h does not cause a sudden charge change or potential change on the corresponding bit line 2a-2h.

Next, in a read state, as shown in FIG. 2, the corresponding word line 1a-1d is then activated substantially simultaneously in order to activate the memory cell 3 that is to be addressed, and the additional word lines 6a-6d are deactivated up to the additional word line 6a-6d, which can be used to connect the dummy memory cells 4 to the bit line 2a-2h that is adjacent to the bit line 2a-2h connected to the memory cell 3 that is to be read. In one example, the significance of this for the memory cell 3′ is that the word line 1a is activated in the read state. The content of the memory cell 3′ can be read by the sense amplifier 9 through the bit line 2c after amplification. At the same time or before the word line 1a is activated, the additional word lines 6a, 6c, 6d activated in the pre-charged state are deactivated so that the dummy memory cells 4 connected thereto are isolated from the bit lines 2a2h. The additional word line 6b remains activated and, thus, causes the capacitances of the adjacent bit lines 2a and 2d each to be increased by the amount of the capacitance of a dummy memory cell 4.

The features of the invention that are disclosed in the description above, in the claims and in the drawings can be significant both individually and in any desired combination for the purpose of implementing the invention in its various embodiments.

We claim:

1. An integrated memory circuit, comprising:
word lines including:
a first word line; and
a second word line;
a word line control circuit:
having an input for receiving an address; and
adapted to activate at least said first word line based upon the address received at said input, said first and second word lines connected to said word line control circuit;
bit lines including:
a first bit line; and
a second bit line;
a memory cell connected to at least said first word line and at least said first bit line, said memory cell addressed through said first word line and having a content read through said first bit line;
at least one capacitance element connected to said second word line;
said second word line being adapted to apply said at least one capacitance element to said second bit line adjacent an activated said first bit line upon activation of said second word line; and
said word line control circuit adapted to apply said at least one capacitance element to said second bit line through said second word line during activation of said first word line.

2. The integrated memory circuit according to claim 1, including at least one dummy memory cell, said at least one capacitance element being contained in said at least one dummy memory cell.

3. The integrated memory circuit according to claim 1, wherein:
said memory cell has a given capacitance when addressed; and
said at least one capacitance element substantially has said given capacitance.

4. The integrated memory circuit according to claim 1, wherein:
said first bit line is a plurality of first bit lines;
each of said first bit lines has an associated adjacent bit line to form respective bit line pairs; and
one of a plurality of sense amplifiers is connected to each of said bit line pairs.

5. The integrated memory circuit according to claim 1, wherein:
said bit lines include a plurality of first and second bit lines having capacitance elements; and
said second word line is connected to apply said capacitance elements to every second one of said first and second bit lines when said second word line is activated.

6. The integrated memory circuit according to claim 1, wherein:
said word lines include a plurality of second word lines having a respective plurality of capacitance elements; and
said capacitance elements are adapted to be applied to different ones of said bit lines.

7. The integrated memory circuit according to claim 1, wherein said second word line is adapted to apply said at least one capacitance element to said second bit line adjacent an activated said first bit line substantially simultaneously upon activation of said second word line.

8. An integrated memory circuit, comprising:
word lines including:
a first word line; and
a second word line;
a word line control circuit:
having an input for receiving an address; and
being programmed to activate at least said first word line based upon the address received at said input, said first and second word lines connected to said word line control circuit;
bit lines including:
a first bit line; and
a second bit line;
a memory cell connected to at least said first word line and at least said first bit line, said memory cell addressed through said first word line and having a content read through said first bit line;
at least one capacitance element connected to said second word line;
said second word line being adapted to apply said at least one capacitance element to said second bit line adjacent an activated said first bit line upon activation of said second word line; and
said word line control circuit being programmed to apply said at least one capacitance element to said second bit line through said second word line during activation of said first word line.

9. A method for reading a data item from a memory cell through a first bit line connected to the memory cell, which comprises:
providing a second bit line adjacent the first bit line;
increasing capacitance of the second bit line by connecting a capacitance to the second bit line;
reading the memory cell by activating a word line and causing a charge stored in the memory cell to flow onto the first bit line; and
amplifying a charge difference between the first bit line and the adjacent second bit line and reading the data item stored in the memory cell through the first bit line.

10. The method according to claim 9, which further comprises selecting the capacitance of the adjacent bit line to make capacitances of the bit line and of the adjacent bit line substantially the same.

11. The method according to claim 10, which further comprises:
providing first word lines; and
following the step of connecting the adjacent bit line to the capacitance, and before activating one of the first word lines, providing the bit line and the adjacent bit line with a predetermined voltage potential.
